(19) United States
(12) Patent Application Publication
(10) Pub. No.: US 2004/0075168 A1
(43) Pub. Date: Apr. 22, 2004

(54) Semiconductor device bonded on circuit board via coil spring

(76) Inventor: Kosuke Azuma, Kanagawa (JP)

Correspondence Address: DICKSTEIN SHAPIRO MORIN & OSHINSKY LLP, 1177 AVENUE OF THE AMERICAS (6TH AVENUE), 41 ST FL., NEW YORK, NY, 10036-2714, US

(21) Appl. No.: 10/682,822

(22) Filed: Oct. 10, 2003

(30) Foreign Application Priority Data
Oct. 17, 2002 (JP) 303627/2002

(51) Int. Cl. H01L 23/34

(52) U.S. Cl. 257/718

(57) ABSTRACT

Disclosed herein is a semiconductor device in which a semiconductor chip is bonded at its pad to an electrode of a circuit substrate via a coil spring by solder-connecting both ends of the spring respectively to the pad and the electrode. There is provided a material having low solder wettability that covers at least part of the surface of the coil spring, so that the solder is prevented from being sucked into the Interior of the coil spring.

A semiconductor device of the present invention comprises a semiconductor chip, a circuit substrate and a coil spring electrically connecting the semiconductor chip and the circuit substrate by a solder. In order to prevent the solder from being sucked into the interior of the coil spring, a material having low wettability by the solder is formed on the surface of the coil spring.

### BACKGROUND OF THE INVENTION

1. Field of the Invention

The present invention relates to a semiconductor device in which electrical connection between a pad of semiconductor chip and an electrode of a circuit substrate is performed via a coil spring. The present invention also relates to a method of manufacturing such semiconductor device.

2. Description of the Prior Art

In order to comply with increase in processing speed of a semiconductor chip, it has been known and put into practice use that a semiconductor chip is mounted or connected to a circuit substrate in a flip chip bonding manner to shorten interconnection length there between.

In the flip chip bonding manner, a pad formed on the semiconductor chip and an electrode of the circuit substrate are directly bonded together via, for example, a solder ball. This method can provide the shortened interconnections, thereby preventing the occurrence of floating capacitance and inductance and permitting high-speed processing.

However, due to the direct bonding of the pads of the semiconductor component and the electrodes of the circuit substrate, stresses caused by the difference in thermal expansion between the semiconductor chip and the circuit substrate are concentrated in the bonding area of the chip and board to damage those areas. It has been proposed in the Japanese Patent Laid-Open No. 2002-151550 such a device that is shown in FIG. 1. In this device, each pad 102 of a semiconductor chip 101 and each electrode 105 of a circuit substrate 104 are bonded via an electrically conductive coil spring 107 by the both ends of the spring 107 are solder-connected respectively to a solder bump 103 of the chip 101 and a solder electrode 106 of the substrate 104. With this construction, the coil spring 107 can absorb the differences in thermal expansion between the chip 101 and the circuit substrate 104.

The present inventor, however, recognized that each of the solders 103 and 106 is sucked into the interior of the coil spring due to the capillary phenomenon, resulting to decrease in bonding strength between the coil spring 107 and the chip 101 and/or between the coil spring 107 and the substrate 104. The inventor has made it clear that this decrease in strength is due to the fact that the substantive amount of solder 103 and/or 106 has flown into the coil spring 107.

### SUMMARY OF THE INVENTION

According to the present invention, there is provided a semiconductor device in which a pad of a semiconductor chip is solder-bonded to an electrode of a circuit substrate via a coil spring, at least on inner surface of which is covered with a material of low wettability against a solder.

The capillary phenomenon that a solder is sucked into the interior of the coil spring during solder bonding is prevented by the material of low solder. As a result, in the bonding area between the coil spring and the pad or the bonding area between the coil spring and the electrode, the solder remains in an amount necessary for solder bonding. Strong soldering bonding can be obtained by this action.

### BRIEF DESCRIPTION OF THE DRAWINGS

The above and other objects, advantages and features of the present invention will be more apparent from the following description taken in conjunction with the accompanying drawings, in which:

FIG. 1 is a view showing a semiconductor device according to the prior art;

FIG. 2 is a sectional view of a bonding area of the prior art;

FIG. 3 is a view of a semiconductor device of the first embodiment of the invention;

FIG. 4 is an enlarged view of a coil spring 7 of FIG. 3;

FIG. 5 is a schematic representation of an example of the second embodiment of the invention;

FIG. 6 is a schematic representation of an example of the second embodiment of the invention;

FIG. 7 is a schematic representation of an example of the fourth embodiment of the invention;

FIG. 8 is a schematic representation of an example of the fourth embodiment of the invention;

FIG. 9 is an explanatory drawing of a method of forming a coil spring of FIG. 8;

FIG. 10 is an explanatory drawing of a method of forming a coil spring in which a material of high wettability by the solder is formed further on an outer surface in FIG. 8;

FIGS. 11(a) and (b) are each an explanatory drawing of a method of manufacturing a semiconductor device of the first embodiment of the invention; and

FIGS. 12(c) and (d) are each an explanatory drawing of a method of manufacturing a semiconductor device of the first embodiment of the invention (continued from FIGS. 11(a) and (b))

### DETAILED DESCRIPTION OF THE PREFERRED EMBODIMENTS

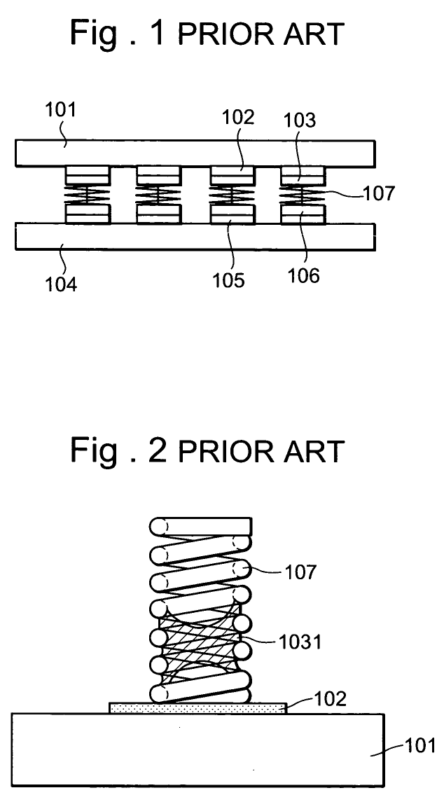

Before describing of the present invention, the prior art will be further explained in detail with reference to FIG. 2 in order to facilitate the understanding of the present invention. FIG. 2 shows an enlargement view of the FIG. 1 device and corresponds to the solder bonding between the coil spring 107 and the pad 102 of the semiconductor chip 101. As shown in the figure, the solder, which has been originally formed on the pad 102 as a solder bump, is sucked up along an inner side surface of the coil spring 107 as indicated by the reference numeral 1031. For this reason, the amount of solder which remains in the solder bonding area decrease. As a result, the strength of solder bonding decrease.

The invention will be now described hereinbelow with reference to illustrative embodiments. Those skilled in the art will recognize that many alternative embodiments can be accomplished using the teachings of the present invention and that the invention is not limited to the embodiments illustrated for explanatory purposes.

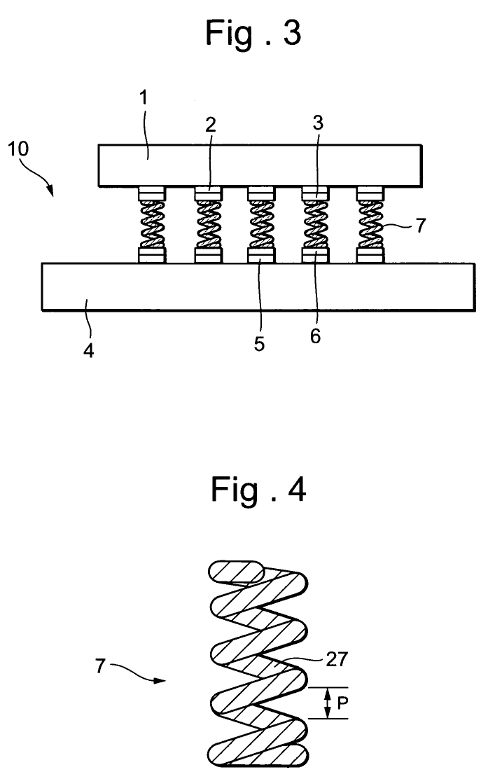

FIG. 3 is a side view showing the configuration of a semiconductor device in the first embodiment of the invention and FIG. 4 shows an example of coil spring used in the flip chip bonding of this semiconductor device. This semiconductor device 10 is comprised by a semiconductor chip 1, a circuit substrate 4 and a coil spring 7. The semiconductor chip 1 is formed from Si, GaAs, Ge, etc. The circuit substrate is formed from glass epoxy, alumina, ceramics, etc. The coil spring 7 is formed from a material of high electrical conductivity, such as Cu. The coil spring 7 used in this embodiment is fabricated by winding a Cu conductive wire having a thickness of 30 μm and has a length of 500 μm, a diameter of 150 μm and a pitch of 25 μm. The pitch called here refers to. “P” shown in FIG. 4. A plurality of pads 2 are formed on a surface of the semiconductor chip 1 and a plurality of electrodes 5 are formed on a surface of the circuit substrate 4. In this embodiment, the diameter of the pad 2 and electrode 5 is 150 μm, the same value as the diameter of the coil spring 7. The pad 2 and electrode 5 are formed from Al (aluminum), Ni (nickel), Cu (copper), etc.

The semiconductor chip 1 and circuit substrate 4 are arranged in such a manner that the surface on which the pads 2 are formed and the surface on which the electrodes 5 are formed are opposed to each other. A solder 3 formed from a Pb—Sn alloy is formed on the surface of the pad 2 and a solder 6 formed from a similar alloy is formed on the surface of the electrode 5. By use of these solders the pad 2 and an end of the coil spring 7 are bonded together and the electrode 5 corresponding to this pad and the other end of the coil spring 7 are bonded together. As shown in FIG. 4, a material 27 of low solder wettability is formed on the surface of the coil spring 7 so that the solder is not sucked into the interior of the coil spring 7. As a result, the solder remains on the pad 2 and electrode 5 in an amount necessary for the bonding with the coil spring 7 and strong solder bonding can be obtained.

A semiconductor device of this embodiment can be manufactured by the following procedure.

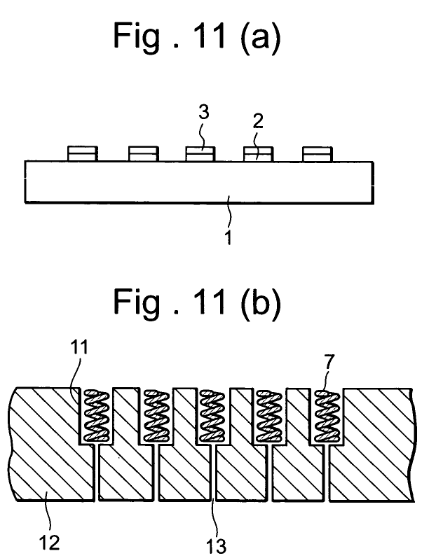

First, as shown in FIG. 11(a), a bonding pad 2 is formed on a surface of a semiconductor chip 1 and a solder 3 is formed on this bonding pad 2. The solder 3 can be formed by the ball mounting method, a printing method using a mask, the plating method, etc.

Next, as shown in FIG. 11(b), a coil spring 7 with the material 27 of low solder wettability is supplied and arranged in each spring positioning hole 11 of a jig 12 in an upright manner. It is desirable that the jig 12 be formed from a material having a coefficient of thermal expansion close to that of the semiconductor chip 1 and heat resistance. The spring positioning hole 11 is formed by a processing method using a drill, a laser, etc. When the diameter of the spring positioning hole 11 is about 10 μm larger than the diameter of the coil spring 7, it becomes easy to set the coil spring 7. An evacuation hole 13 is provided on the back surface of the jig 12.

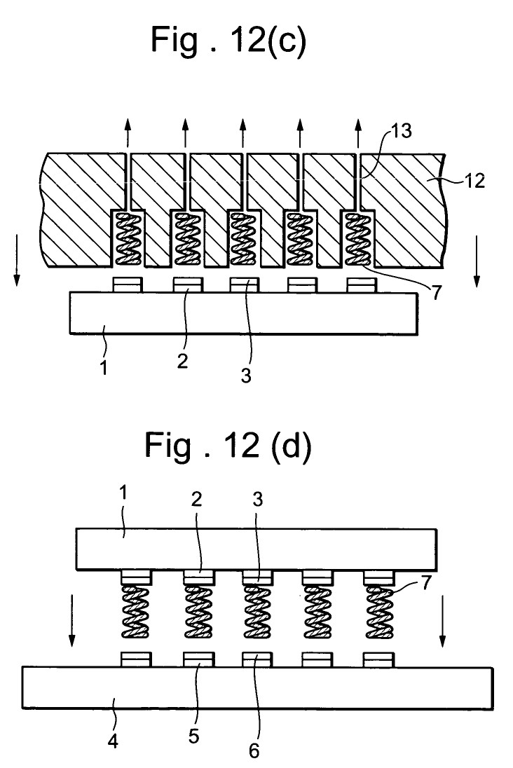

Next, as shown in FIG. 12(c), the jig 12 is inverted with the coil spring 7 kept in the positioning hole 11 by evacuating air from the evacuation hole 13. Subsequently, the jig 12 is moved in such a manner that each coil spring 7 is positioned above the solder 3 formed on the semiconductor chip 1. Incidentally, a flux is applied beforehand to the solder 3 or coil spring 7. Subsequently, with the semiconductor chip 1 and the jig 12 kept as one piece, local heating treatment is performed by a reflow furnace or the pulse heat method. At this time, the solder 3 is melted and one end of each coil spring 7 is bonded to the pad 2 by the solder 3. Although the melted solder is sucked into the interior of the coil spring of the prior art, the material 27 of low solder wettability of this invention prevents the melted solder 3 from being sucked into the coil spring 7. Subsequently, by performing the cleaning and removal of the flux, a semiconductor chip in which one end of the coil spring 7 is bonded to the pad 2 by the solder 3 is obtained.

Next, as shown in FIG. 12(d), a circuit substrate 4 on which electrodes 5 are formed is prepared. The electrode 5 is fabricated from Cu, Ni, Au, etc. The circuit substrate 4 is formed from glass epoxy, alumina, ceramics, etc. A solder 6 is formed on the electrode 5. Subsequently, the semiconductor chip 1 to which the coil springs 7 are bonded is reversed and the semiconductor chip 1 is mounted on the circuit substrate 4 in such a manner that the coil spring 7 is positioned above the solder 6 formed on the circuit substrate 6.

Next, the same local heating treatment as described above is performed and the solder 6 is melted, whereby the end of the coil spring 7 is bonded to the electrode 5 by the solder 6. In this case, the compositions of the solder 3 and the solder 6 are adjusted so that the melting point of the solder 6 becomes lower than the melting point of the solder 3. As a result of this, the other end of the coil spring 7 can be bonded to the electrode 5 by the solder 6 without affecting the bonded state already completed between coil spring 7 and solder 3. Other embodiments of this invention can be manufactured in the same manner mentioned above.

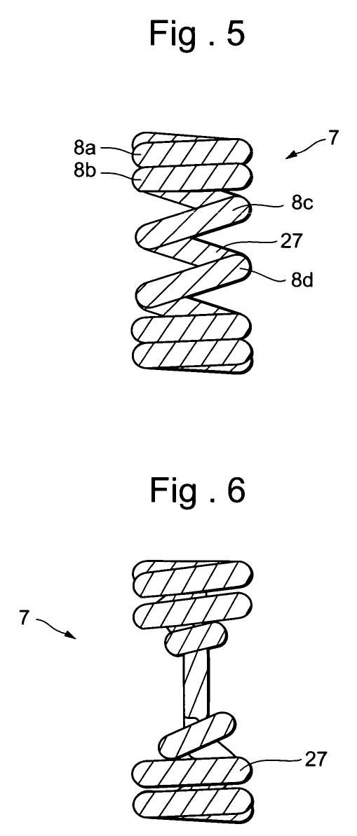

In the second embodiment, the shape of the coil spring 7 in the first embodiment is changed. Examples of shape of the coil spring 7 are shown in FIGS. 5 and 6. FIG. 5 shows an example of coil spring in which the pitch between ends 8a and 8b is smaller than the pitch between middle parts 8c and 8d. As shown in this example, the pitch of smaller one can be set to 0. By adopting this shape, the contact area between the end of the coil spring 7 and the solder increases and stronger solder bonding can be obtained. FIG. 6 shows a coil spring in which the middle part is linear. By adopting this shape, the space in the interior of the coil spring decreases and the amount of solder sucked into the interior of the coil spring can be reduced. As a result, the solder remains on the pad and electrode in an amount necessary for solder bonding and strong solder bonding can be obtained.

In the third embodiment, the material of low solder wettability in the first embodiment is changed. Insulating materials, such as resin and metal oxide, and metals of low wettability, etc. can be used as the material of low wettability 27 in FIG. 4. When resin is used, a resin layer can be formed on the coil spring surface by applying a prescribed resin to the surface of a coil spring formed from a material of good electrical conductivity. When a metal oxide film is used, a metal oxide film can be formed on the coil spring surface by heating a metallic coil spring in an oxygen atmosphere. For example, when the coil spring is formed from Cu, the metal oxide film becomes a copper oxide film. When a metal of low wettability is used, a metal film of low wettability can be formed on the coil spring surface by using electrolysis plating or electroless plating. Cr etc. can be used as a metal material of low wettability.

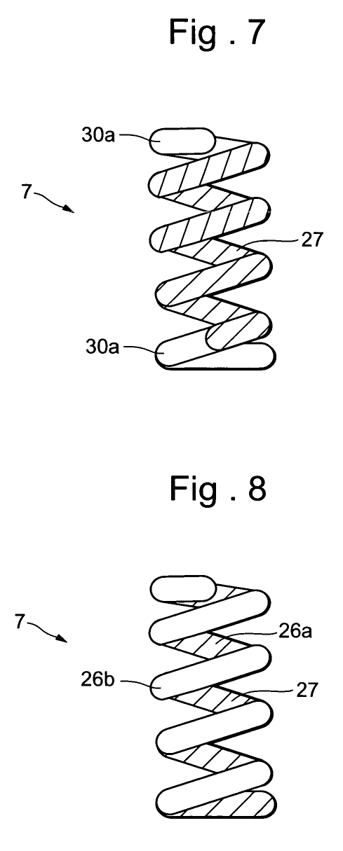

In the fourth embodiment, the place where a material of low wettability is formed in the first embodiment is changed. A material of low wettability may be formed on the whole surface of the coil spring or may be partly formed as shown in FIGS. 7 and 8. In FIG. 7, the material of low wettability 27 is formed in parts other than ends 30a. By adopting this configuration, it is possible to ensure wettability at the ends 30a where the solder must adhere. As a result, stronger solder bonding can be obtained. Furthermore, by forming a material of high wettability at the 30a where a material of low wettability is not formed, the ends 30a and the solder are brought into closer contact with each other and stronger solder bonding can be obtained. In FIG. 8, the material of low wettability 27 is formed on an inner side surface 26a of the coil spring. If the material of low wettability 27 is formed on the inner side surface 26a of the coil spring, it is possible to reduce the degree of the capillary phenomenon. As a result, the solder remains on the pad 2 and electrode 5 in an amount necessary for solder bonding and it is possible to adequately obtain the effect that solder bonding becomes strong. Also, by preventing the material of low wettability 27 from being formed on an outer side surface 26b of the coil spring, the outer side surface 26b of the coil spring and the solder come into close contact with each other and stronger solder bonding can be obtained.

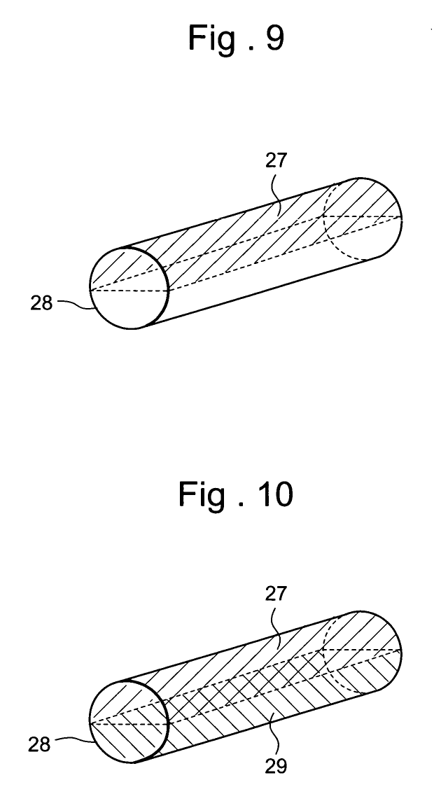

In forming a material of low wettability in part of the coil spring, the following method can be adopted. When resin is used as a material of low wettability, a prescribed resin is applied to a necessary place. When a metal oxide film is used as a material of low wettability, a metallic coil spring is first heated in an oxygen atmosphere and a metal oxide film is formed on the whole surface of the metallic coil spring. By causing the part 30a of FIG. 7 and the part 26b of FIG. 8 in the metal oxide film to fly by laser irradiation thereby to remove them, it is possible to form a metal oxide film in parts other than the end and outer side surface of the coil spring as shown in FIGS. 7 and 8. When the metal material of low wettability 27 is formed on the inner side surface 26a of the coil spring as shown in FIG. 8, the following method can be adopted. First, as shown in FIG. 9, a metal of low wettability 271 is formed by the plating method etc. only on one side of a conductive wire 28. By winding this conductive wire 28 in such a manner that the metal of low wettability 271 is provided on the inner side surface of the coil spring, it is possible to obtain the coil spring in which the metal of low wettability 271 is formed on the inner side surface.

Stronger solder bonding can be obtained when a material of high solder wettability is formed on the outer side surface in addition to the formation of the metal of low wettability on the inner side surface of the coil spring. This is due to the following principle. Because the material of low wettability is formed on the inner side surface in the interior of the coil spring, the suction of the solder into the interior of the coil spring is suppressed. On the other hand, because the material of high wettability is formed on the outer side surface of the coil spring, the solder spreads up along the outer side surface of the coil spring. At this time, the sucking up of the solder into the interior of the coil spring is more suppressed because a large amount of solder gathers on the outer side surface. At the same time, a larger amount of solder comes into contact with the outer side surface of the coil spring. Owing to the combined effects of the two phenomena, strong solder bonding can be obtained. For example, Au can be used as the material of high wettability.

A coil spring in which a material of low wettatbility is formed on the inner side surface and a material of high wettatbility is formed on the outer side surface can be made by the following method. First, as shown in FIG. 10, a material of low wettability 27 such as Cr is formed on one half surface of the conductive wire 28 and a material of high wettability 29 such as Au is formed on the other half surface. Next, this conductive wire 28 is wound in such a manner that the material of low wettability 27 is provided on the inner side surface to form a coil spring.

It is apparent that the present invention is not limited to the above embodiments, but may be modified and changed without departing from the scopes and spirits of the invention.

What is claimed is:

1. A semiconductor device, comprising:
a semiconductor chip having a pad and a solder formed on said pad;
a circuit substrate having an electrode;
a coil spring being electrically connected at its one end portion to said pad and its another end portion to said electrode, said coil spring being constructed such that the solder formed on said pad is suppressed from being sucked into interior of said coil spring.

2. A semiconductor device of claim 1, at least a part of a surface of said coil spring is covered with a material of low solder wettability.

3. The semiconductor device of claim 2,
wherein a pitch of said coil spring at the end portion thereof is smaller than a pitch in a middle part thereof.

4. The semiconductor device of claim 2,
wherein a middle part of said coil spring is substantially straight.

5. The semiconductor device of claim 2,
wherein said material of low solder wettability is formed on a whole surface of said spring coil.

6. The semiconductor device of claim 2,
wherein said material of low solder wettability is formed on an inner surface of said coil spring.

7. The semiconductor device of claim 6,
wherein a material of high solder wettability is formed on an outer surface of said coil spring.

8. The semiconductor device of claim 2,
wherein said material of low solder wettability is an insulating material.

9. The semiconductor device of claim 8,
wherein said coil spring is formed from a metal material and said insulating material is an oxide film of said metal material.

10. The semiconductor device of claim 2,
wherein said material of low solder wettability is a metal having low solder wettability.

11. The semiconductor device of claim 10,
wherein said metal is Cr.

12. The semiconductor device of claim 7,
wherein said material of high solder wettability is a metal having high solder wettability.

13. The semiconductor device of claim 12,
wherein said metal is Au.

14. The semiconductor device of claim 1, a middle part of said coil spring is substantially straight.
